(19) United States
(12) Patent Application Publication
(10) Pub. No.: US 2024/0407204 A1
(43) Pub. Date: Dec. 5, 2024

(54) Display Device

(71) Applicant: LG Display Co., Ldt., Seoul (KR)

(72) Inventors: Sang Ho Kim, Paju-si (KR); Tae Yeon Yoo, Paju-si (KR)

(21) Appl. No.: 18/659,747

(22) Filed: May 9, 2024

(30) Foreign Application Priority Data
May 31, 2023 (KR) 10-2023-0070260

(51) Int. Cl. H10K 59/124; H10K 59/131

(52) U.S. Cl. CPC H10K 59/124; H10K 59/131

(57) ABSTRACT

A display device according to the present specification may include: a substrate including a display area, a non-display area, and a plurality of sub-pixels arranged in the display area, each of the plurality of sub-pixels including an emission layer in the display area; an insulating layer on the substrate; a plurality of wires spaced apart from each other on the insulating layer in the non-display area; and a support layer on each of the plurality of wires in the non-display area. At least one of the plurality of wires may be include a metallic material, and the support layer may include an organic material.

### CROSS-REFERENCE TO RELATED APPLICATION

This application claims priority to and the benefit of Republic of Korea Patent Application No. 10-2023-0070260, filed May 31, 2023, the disclosure of which is incorporated herein by reference in its entirety.

### BACKGROUND

### Field

The present specification relates to a display device.

### Discussion of Related Art

Display devices are roughly divided into inorganic light emitting display devices and organic light emitting display devices depending on the material of the emission layer. An organic light emitting display device of an active matrix type includes an organic light emitting diode (hereinafter, referred to as “OLED”) that emits light by itself, and has an advantage in that the response speed is fast, the luminous efficiency and luminance are good, and the viewing angle is wide. In an organic light emitting display device, an OLED is formed in each pixel. The organic light emitting display device has a fast response speed, is excellent in terms of luminous efficiency, luminance and viewing angle, and provides an excellent contrast ratio and color reproducibility since it can express the black grayscale in complete black.

In addition, the multimedia capability of mobile devices is being improved. For example, cameras are being embedded in smartphones by default, and the resolution of these cameras is increasing to the level of existing digital cameras. However, the front camera of a smartphone limits the screen design, making screen design difficult. To reduce the space occupied by the camera, the display device may include a notch or punch hole.

Among these, the screen design called a punch hole may make it easier for the camera to receive light by forming a hole in the space needed by the camera.

However, the punch hole structure may cause a problem in that the display device, which is vulnerable to moisture and oxygen, becomes prone to deterioration by forming a hole in the screen. Therefore, there is a need for a scheme to prevent moisture and oxygen from penetrating along the end portion of the hole in the display device.

### SUMMARY

An object to be achieved according to an embodiment of the present specification is to provide a display device that is capable of preventing damage to the elements due to moisture penetrating through the hole from the outside.

An object to be achieved according to an embodiment of the present specification is to provide a display device that is capable of preventing a portion of plural metal wires from being separated.

Problems of the present specification are not limited to the above-mentioned problems, and other problems which are not mentioned will be clearly understood by those skilled in the art from the following disclosure.

A display device according to one or more embodiments of the present specification may include: a substrate including a display area, a non-display area, and a plurality of sub-pixels arranged in the display area, each of the plurality of sub-pixels including an emission layer in the display area; an insulating layer on the substrate; a plurality of wires spaced apart from each other on the insulating layer in the non-display area; and a support layer on each of the plurality of wires in the non-display area, wherein at least one of the plurality of wires includes a metallic material, and the support layer includes an organic material.

A display device according to one or more embodiments of the present specification may include: a substrate including a display area, a non-display area, and a plurality of sub-pixels arranged in the display area, each of the plurality of sub-pixels including an emission layer in the display area; an insulating layer on the substrate; a wire on the insulating layer in the non-display area, the wire including a metal material; a wire on the insulating layer in the non-display area, the wire including a metal material; an organic material layer on the support layer and the insulating layer in the non-display area, wherein the wire and the support layer may have a specific thickness, wherein a first portion of the organic material layer on the support layer is spaced apart by the specific thickness from a second portion of the organic material layer on the insulating layer, and wherein the first portion of the organic material layer on the support layer and the second portion of the organic material layer on the insulating layer include a same material as the emission layer in the display area.

A display device according to one or more embodiments of the present specification may include: a substrate including a display area, a non-display area, and a plurality of sub-pixels arranged in the display area, each of the plurality of sub-pixels including an emission layer in the display area; an insulating layer on the substrate; a wire on the insulating layer in the non-display area, the wire including a metallic material; a support layer on the wire without being on the insulating layer, the support layer including an organic material; a first organic material layer on the support layer in the non-display area; and a second organic material layer on the insulating layer in the non-display area, the second organic material layer disconnected from the first organic material layer at least through the wire.

According to the present specification, a display device is provided that blocks the moisture penetration path to the elements by arranging a structure around the hole. Specifically, a disconnection structure is implemented for the organic material layer by using a structure disposed around the hole, so that the display device according to the present specification may block moisture that penetrates toward the elements along the organic material layer through the hole. Accordingly, the lifespan of the display device may be improved, which in turn enables low-power driving of the production process in terms of reducing production energy.

According to the present specification, it is possible to provide a display device that prevents a portion of the wires from being separated by forming a support layer at the topmost end of the structure around the hole.

Effects according to the present specification are not limited to the content exemplified above, and more various effects are included in the present specification.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a view illustrating a display device according to an embodiment of the present specification;

FIG. 2 is an enlarged view of region A in FIG. 1 according to an embodiment of the present specification;

FIG. 3 is a cross-sectional view of a sub-pixel taken along line I-I′ in FIG. 1 according to an embodiment of the present specification;

FIG. 4 is a cross-sectional view taken along II-II′ of region A in FIG. 2 according to an embodiment of the present specification;

FIG. 5 is an enlarged view of region B in FIG. 4 according to an embodiment of the present specification;

FIGS. 6A-6C are enlarged cross-sectional views of a wire according to embodiments of the present specification;

FIG. 7 is an enlarged cross-sectional view of a wire according to another embodiment of the present specification;

FIG. 8 is a view depicting an end portion being separated from the wire according to an embodiment of the present specification;

FIG. 9 is a view illustrating a penetration path of moisture and oxygen according to an embodiment of the present specification;

FIG. 10 is an enlarged cross-sectional view of a structure according to an embodiment of the present specification;

FIG. 11 is a cross-sectional view of a structure according to another embodiment of the present specification;

FIG. 12 is an enlarged view of region D in FIG. 11 according to an embodiment of the present specification; and

FIGS. 13A through 13D are views illustrating a method of manufacturing a display device according to an embodiment of the present specification.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising”, “including” and “having” used herein are generally intended to allow other components to be added unless the terms are used with the term “only”. References to the singular shall be construed to include the plural unless expressly stated otherwise.

In interpreting the components, it should be understood that an error range is included even when there is no separate explicit description.

In the case of the description of the positional relationship, for example, if the positional relationship of the two parts is described as “on”, “above”, “bottom”, “next to”, etc., one or more other parts may be located between the two parts unless the term “directly” or “immediately” is explicitly used.

In the description for the embodiments, the first, second, etc. are used to describe various components, but these components are not limited by these terms. These terms are only used to distinguish one component from another. Therefore, the first component mentioned below may be a second component within the technical spirit of the present disclosure.

Throughout the specification, the same reference numerals refer to the same component.

The features of each of the various embodiments may be combined or combined with each another, in whole or in part, and various technical interlocking and driving may be possible, and each of the embodiments may be implemented independently of each other or in conjunction with each other.

As used herein, “a display apparatus” may include a display apparatus in a narrow sense, such as a liquid crystal module (LCM), an organic light-emitting diode (OLED) module, or a quantum dot (QD) module, which includes a display panel and a driver for driving the display panel. It may also include a set electronic apparatus or a set device or set apparatus, such as a laptop computer, a television set, a computer monitor, an automotive display apparatus or an equipment display apparatus including another form in a vehicle, and a mobile electronic apparatus, such as a smart phone or an electronic pad, which is a complete product or finished product including the LCM, the OLED module, and the QD module.

The display device in this specification may include the display device itself in a narrow sense, an application product including a display in a narrow sense, or even a set device being an end-consumer device.

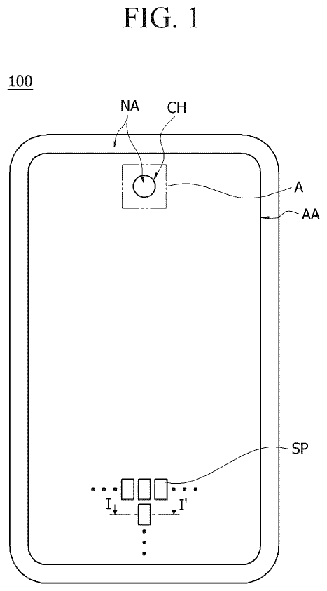

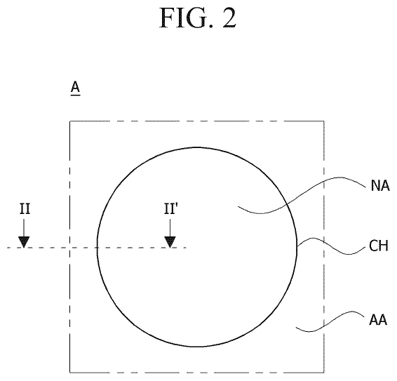

FIG. 1 is a view illustrating a display device according to an embodiment of the present specification, and FIG. 2 is an enlarged view of region A in FIG. 1 according to an embodiment of the present specification.

With reference to FIG. 1, the display device 100 may include an optical module and a display panel. For example, the optical module may include a sensor and a camera, but embodiments of the present specification are not limited thereto.

The display panel may include a display area AA and a non-display area NA. The display area AA may be a region where an image is displayed. For example, the display area AA may be an active area, but embodiments of the present specification are not limited thereto. The non-display area NA may be located around the display area. For example, the non-display area NA may be a non-active area or a bezel area, but embodiments of the present specification are not limited thereto.

Since the hole CH is disposed inside the display area AA of the display panel, the non-display area NA may be reduced and the display area AA may be enlarged. A product with an expanded display area AA may increase the level of user's screen immersion. For example, the sensor may be disposed in correspondence to the hole CH. For example, the sensor may be a distance monitoring sensor or a face recognition sensor, but embodiments of the present specification are not limited thereto.

The hole CH may be provided as a single instance as shown in region A of FIG. 1, but embodiments of the present specification are not limited thereto. For example, the number and shape of the holes CH may be formed in various modified ways. For instance, two or more holes may be arranged inside the display area AA; a camera may be disposed in the first hole, and sensors such as a distance detection sensor or a face recognition sensor may be disposed in the second hole, but embodiments of the present specification are not limited thereto.

With reference to FIG. 2, region A may include a portion of the display area AA and a hole CH, and the non-display area NA of region A may include the hole CH.

A plurality of sub-pixels SP may be arranged in the display area AA of the display device 100. The display device 100 according to an embodiment of the present specification may be a display such as an organic light emitting diode (OLED) display, a quantum dot display, or a micro light emitting diode (micro-LED) display, but embodiments of the present specification are not limited thereto.

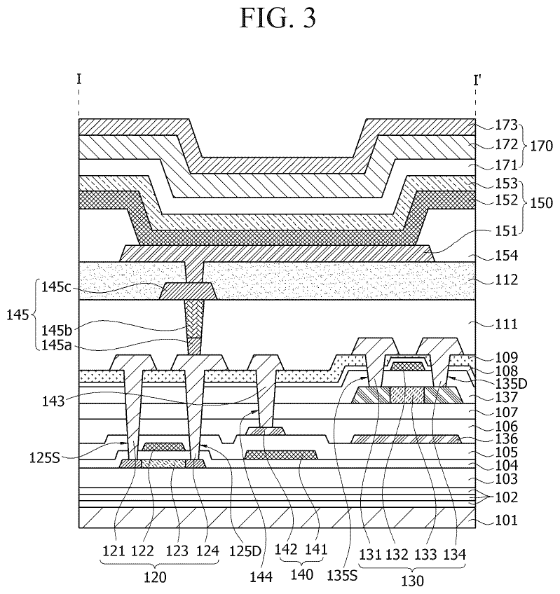

FIG. 3 is a cross-sectional view of a sub-pixel taken along line I-I′ in FIG. 1.

With reference to FIG. 3, the display device 100 may include a substrate 101, a first buffer layer 102, and a second buffer layer 103. A first thin film transistor 120 may be disposed on the second buffer layer 103. For example, the substrate 101 may be disposed in the display area AA and the non-display area NA.

The first thin film transistor 120 may include a first semiconductor layer 123, a first gate electrode 122 disposed on the first semiconductor layer 123, and a gate insulating film 104. The first thin film transistor 120 may be disposed in the display area AA.

The first buffer layer 102 may delay the diffusion of moisture or oxygen that has penetrated into the substrate 101. The first buffer layer 102 may be formed by alternately stacking silicon nitride (SiNx) and silicon oxide (SiOx) at least once, but embodiments of the present specification are not limited thereto.

The second buffer layer 103 may protect the first semiconductor layer 123 and may block various types of defects flowing from the substrate 101. The second buffer layer 103 may be made of amorphous silicon (a-Si), silicon nitride (SiNx), or silicon oxide (SiOx), but embodiments of the present specification are not limited thereto.

The first semiconductor layer 123 of the first thin film transistor 120 may be made of a polycrystalline semiconductor layer, and the first semiconductor layer 123 may constitute a channel region, a source region, and a drain region.

Since the polycrystalline semiconductor layer has higher mobility than the amorphous semiconductor layer and the oxide semiconductor layer, energy consumption power can be low and reliability can be excellent. Hence, the driving transistor may be composed of a polycrystalline semiconductor layer.

A first lower interlayer insulating film 105, a second lower interlayer insulating film 106, and a third buffer layer 107 may be disposed on the first gate electrode 122, but embodiments of the present specification are not limited thereto.

The first gate electrode 122 may be disposed on the gate insulating film 104. The first gate electrode 122 may be arranged to overlap the first semiconductor layer 123.

The second thin film transistor 130 may be disposed on the third buffer layer 107. A light shielding layer 136 may be disposed under a region corresponding to the second thin film transistor 130.

With reference to FIG. 3, the light shielding layer 136 may be disposed on the first lower interlayer insulating film 105 in the region corresponding to the second thin film transistor 130, and the second semiconductor layer 133 of the second thin film transistor 130 may be disposed on the second lower interlayer insulating film 106 and the third buffer layer 107 so as to overlap the light shielding layer 136. An upper gate insulating film 137 may be disposed on the second semiconductor layer 133 so as to insulate the second gate electrode 132 and the second semiconductor layer 133.

A first upper interlayer insulating film 108 may be disposed on the second gate electrode 132. A second upper interlayer insulating film 109 may be disposed on the first upper interlayer insulating film 108. The first gate electrode 122 and the second gate electrode 132 may be a gate electrode.

The first gate electrode 122 and the second gate electrode 132 may be a single layer or a multi-layer made of any one or an alloy of molybdenum (Mo), aluminum (Al), chromium (Cr), gold (Au), titanium (Ti), nickel (Ni), neodymium (Nd), and copper (Cu), but embodiments of the present specification are not limited thereto.

The first and second lower interlayer insulating films 105 and 106 may be made of an inorganic film with a higher hydrogen particle content than the first upper interlayer insulating film 108. Hydrogen particles contained in the first and second lower interlayer insulating films 105 and 106 may diffuse into the polycrystalline semiconductor layer during the hydrogenation process and fill the pores in the polycrystalline semiconductor layer with hydrogen.

Hence, the polycrystalline semiconductor layer may be stabilized, thereby preventing deterioration in the characteristics of the first thin film transistor 120. After the activation and hydrogenation process of the first semiconductor layer 123 of the first thin film transistor 120, the second semiconductor layer 133 of the second thin film transistor 130 may be formed. The second semiconductor layer 133 may be made of an oxide semiconductor. Since the second semiconductor layer 133 is not exposed to the high temperature atmosphere of the activation and hydrogenation process of the first semiconductor layer 123, damage to the second semiconductor layer 133 may be prevented and reliability may be improved.

A second upper interlayer insulating film 109 may be disposed on the first upper interlayer insulating film 108. The second upper interlayer insulating film 109 may include an insulating material.

The second upper interlayer insulating film 109 may include a material different from that of the first upper interlayer insulating film 108. The second upper interlayer insulating film 109 may include a silicon nitride (SiNx) based material, but embodiments of the present specification are not limited thereto.

The first source electrode 121 and the first drain electrode 124 corresponding to the first thin film transistor 120, and the second source electrode 131 and the second drain electrode 134 corresponding to the second thin film transistor 130 may be formed simultaneously through a first source contact hole 125S and a first drain contact hole 125D, and a second source contact hole 135S and a second drain contact hole 135D so as to correspond to their source regions and drain regions.

This may allow a reduction in the number of processes for forming the source and drain electrodes of each of the first thin film transistor 120 and the second thin film transistor 130. The first source electrode 121, the first drain electrode 124, the second source electrode 131, and the second drain electrode 134 may be, but not limited to, a single layer or a multi-layer made of any one or an alloy of molybdenum (Mo), aluminum (Al), chromium (Cr), gold (Au), titanium (Ti), nickel (Ni), neodymium (Nd), and copper (Cu).

A storage capacitor 140 may be disposed between the first thin film transistor 120 and the second thin film transistor 130. As shown in FIG. 3, the storage capacitor 140 may be formed by overlapping a storage lower electrode 141 and a storage upper electrode 142 with the first lower interlayer insulating film 105 interposed therebetween.

The storage lower electrode 141 may be positioned on the lower gate insulating film 104, and may be made of the same material and on the same layer as the first gate electrode 122. Additionally, the storage upper electrode 142 may be electrically connected to the pixel circuit through a storage supply line 143.

For example, the storage upper electrode 142 is exposed through a storage contact hole 144 (or contact hole) penetrating the second lower interlayer insulating film 106, third buffer layer 107, upper gate insulating film 137, first upper interlayer insulating film 108, and second upper interlayer insulating film 109, and is connected to the storage supply line 143.

The third buffer layer 107, the first upper interlayer insulating film 108, and the second upper interlayer insulating film 109 may be an insulating layer, but embodiments of the present specification are not limited thereto.

A first protective layer 111 may be formed on the first thin film transistor 120, the second thin film transistor 130, and the storage capacitor 140. The first protective layer 111 may be made of, but not limited to, at least one organic insulating material, such as acryl resin, epoxy resin, phenolic resin, polyamide resin, or polyimide resin.

For example, the first protective layer 111 may be a first planarization layer, but embodiments of the present specification are not limited thereto. A connection electrode 145 may be formed on the first protective layer 111.

The connection electrode 145 may electrically connect the emission part 150 and the first thin film transistor 120. The connection electrode 145 may be made of the same material as the first source and drain electrodes 121 and 124 and the second source and drain electrodes 131 and 134, and may be made of a single layer or multiple layers.

The connection electrode 145 may penetrate the first protective layer 111 to be electrically connected to the first drain electrode 124 of the first thin film transistor 120. The thickness of the connection electrode 145 may be greater than that of the first and second gate electrodes 122 and 132.

A second protective layer 112 may be formed on the first protective layer 111. The connection electrode 145 may be formed between the first protective layer 111 and the second protective layer 112.

The second protective layer 112 may be made of, but not limited to, at least one of organic insulating materials such as acryl resin, epoxy resin, phenolic resin, polyamide resin, or polyimide resin.

For example, the second protective layer 112 may be a planarization layer, but embodiments of the present specification are not limited thereto.

When the first protective layer 111 and the second protective layer 112 are made of a dielectric material, capacitance may be formed between layers made of metal.

The emission part 150 may be formed on the second protective layer 112. The emission part 150 may include an anode electrode 151, an emission layer 152 on the anode electrode 151, and a cathode electrode 153 on the emission layer 152. A sub-pixel from the plurality of sub-pixels SP may include the emission layer 152 in the display area AA. The connection electrode 145 may electrically connect the emission layer 152 of the sub-pixel and the first thin film transistor 120. The first thin film transistor 120 may be a driving transistor of the sub-pixel.

A bank 154 may be formed to expose the anode electrode 151. The bank 154 may be made of an organic material such as photo acryl, and may be, but not limited to, a translucent material. For example, the bank 154 may be made of an opaque material to prevent light interference between sub-pixels.

An encapsulation part 170 may be formed on the cathode electrode 153. For example, the encapsulation part 170 may block oxygen and moisture from penetrating from the outside to prevent oxidation of the light emitting material and electrode material.

The encapsulation part 170 may include, but not limited to, a first inorganic encapsulation layer 171, an organic encapsulation layer 172 on the first inorganic encapsulation layer 171, and a second inorganic encapsulation layer 173 on the organic encapsulation layer 172. In this specification, for convenience of explanation, the encapsulation part 170 will be described as a part formed by sequentially stacking the first inorganic encapsulation layer 171, organic encapsulation layer 172, and second inorganic encapsulation layer 173.

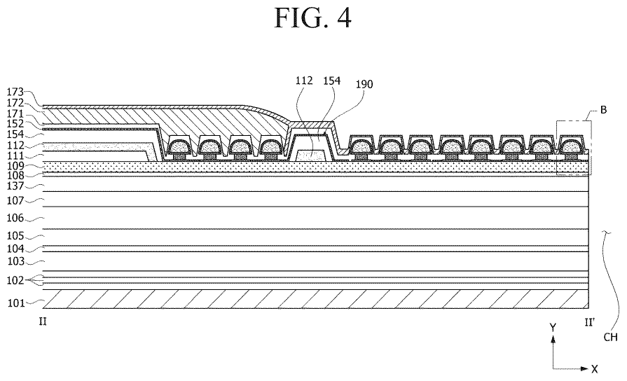

FIG. 4 is a cross-sectional view taken along II-II′ of region A in FIG. 2 according to an embodiment of the present specification.

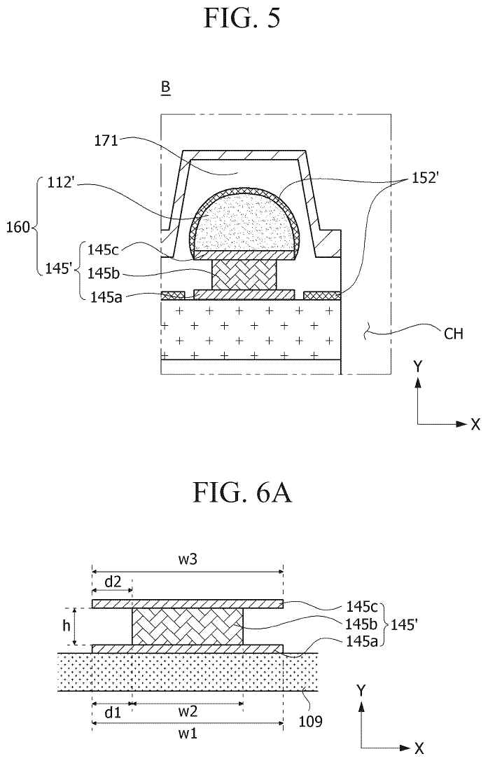

FIG. 5 is an enlarged view of region B in FIG. 4 according to an embodiment of the present specification.

In FIG. 4, parts that are substantially the same as those in FIG. 3 will be omitted and the description will focus on different parts.

With reference to FIGS. 4 and 5, the display device according to an embodiment of the present specification may include a substrate 101, an insulating layer on the substrate 101, a wire 145′ on the insulating layer, and a support layer 112′ on the wire 145′.

The display device 100 may maximize the display area AA by placing the hole CH inside the display area AA as shown in FIG. 1 to thereby increase the level of screen immersion, but an end portion of the organic material layer 152′ may be exposed in the process of forming the hole CH. Here, the organic material layer 152′ may be made of the same material as the emission part 150 of the display area AA, and may be formed together with the emission part 150 in the same process.

As a result, a moisture penetration path may be formed from the end portion of the organic material layer 152′ exposed through the hole CH to the emission part 150. Accordingly, the display device according to an embodiment of the present specification is composed of a structure 160, a disconnection structure for the organic material layer 152′, and a dam 190, so that it is capable of blocking moisture, oxygen, and foreign substances that may move along the moisture penetration path.

For example, to delay and block moisture penetrating from the outside through the exposed end portion of the organic material layer 152′ and prevent damage due to foreign substances, the wire 145′ may be arranged as shown in FIG. 5.

The dam 190 may be disposed on the substrate 101 in the non-display area NA.

The dam 190 may be made of the same material as the second protective layer 112 and the bank 154, and to reduce the non-display area NA, the dam 190 may be arranged as a single instance, without being limited thereto. Additionally, the organic material layer 152′ may be disposed to cover the dam 190. Here, the dam 190 may be disposed on the second upper interlayer insulating film 109, and the thickness of the dam 190 in the Y direction may be different from the thickness of the wire 145′ in the Y direction. For example, the thickness of the dam 190 in the Y direction may be greater than the thickness of the wire 145′ in the Y direction. Therefore, the dam 190 may increase the length of the moisture and oxygen penetration path, more effectively preventing penetration of moisture and oxygen.

The mechanism of moisture and oxygen penetration will be described in detail later.

With reference to FIG. 5, the wire 145′ may be seen through an enlarged cross-sectional view of region B in FIG. 4.

The wire 145′ may include a first metal layer 145a on the insulating layer, a second metal layer 145b directly in contact with the first metal layer 145a, and a third metal layer 145c directly in contact with the second metal layer 145b.

The material of the first metal layer 145a and the material of the third metal layer 145c may be the same. The material of the second metal layer 145b may be different from the material of the first metal layer 145a and the third metal layer 145c. Each wire 145′ may be formed of a metal layer containing titanium (Ti) or aluminum (Al) or may be formed of triple layers such as Ti/Al/Ti, but embodiments of the present specification are not limited thereto.

For example, the first metal layer 145a and the third metal layer 145c may include titanium (Ti), and the second metal layer 145b may include aluminum (Al), but embodiments of the present specification are not limited thereto.

A support layer 112′ may be formed on the wire 145′. For example, the support layer 112′ may be made of the same material as the second protective layer 112. The support layer 112′ may be formed on the same layer as the second protective layer 112. The configuration including the wire 145′ and the support layer 112′ may be referred to as a structure 160. For example, the structure 160 includes the wire 145′ and the support layer 112′, and the structure 160 may be disposed as multiple instances to effectively prevent moisture penetration.

Although it is possible to realize the effect of delaying penetration of moisture and oxygen by disconnecting the organic material layer 152′ through the wire 145′ only, the display device according to an embodiment of the present specification may achieve a better effect on moisture penetration through the support layer 112′, and this effect will be described in detail later.

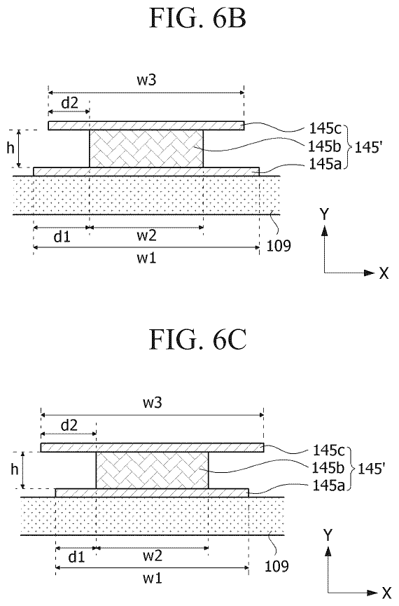

FIG. 6A is an enlarged cross-sectional view of a wire where a protrusion length of the first metal layer 145a is equal to a protrusion length of the third metal layer 145c according to an embodiment of the present specification. FIG. 6B is an enlarged cross-sectional view of a wire where a protrusion length of the first metal layer 145a is longer than a protrusion length of the third metal layer 145c according to an embodiment of the present specification. FIG. 6C is a cross-sectional view of a wire where a protrusion length of the first metal layer 145a is shorter than a protrusion length of the third metal layer 145c according to an embodiment of the present specification. With reference to any of FIGS. 6A-6C, it is possible to prevent or minimize penetration of moisture and oxygen through the structure 160 including only the wire 145′.

For example, in the case of a wire made of a single metal, moisture and oxygen may penetrate into the interior of the display device 100 along the surface of the wire. However, in the case of the display device 100 according to an embodiment of the present specification, penetration of moisture and oxygen may be prevented or minimized by use of the wire 145′ that is formed in triple layers and has a stepped structure.

As shown in FIGS. 6A-6C, in the display device 100 according to an embodiment of the present specification, the widths w1 and w3 of the first metal layer 145a and the third metal layer 145c are formed differently from the width w2 of the second metal layer 145b, so that a stepped structure of the wire 145′ in which the second metal layer 145b is formed to be concave may be implemented. Here, the thickness h of the second metal layer 145b may be adjusted, and as the thickness h of the second metal layer 145b increases, the penetration path of moisture and oxygen becomes longer.

Accordingly, even if moisture and oxygen tending penetrate into the interior of the display device 100 along the surfaces of the first metal layer 145a, the second metal layer 145b, and the third metal layer 145c, the penetration path of moisture and oxygen is lengthened due to the stepped structure and the thickness h of the second metal layer 145b, thereby preventing or minimizing penetration of moisture and oxygen into the interior of the display device 100.

As such, the penetration path of moisture and oxygen may be determined according to the widths of the first metal layer 145a and third metal layer 145c, the difference in width between the first metal layer 145a and the second metal layer 145b, the difference in width between the third metal layer 145c and the second metal layer 145b, the thicknesses of the first metal layer 145a and third metal layer 145c, and the thickness h of the second metal layer 145b; a process such as etching the second metal layer 145b may be performed to increase the length of the penetration path.

Therefore, the width w1 of the first metal layer 145a and/or the width w3 of the third metal layer 145c may be formed to be larger than the width w2 of the second metal layer 145b. The width w1 of the first metal layer 145a may be the same as the width w3 of the third metal layer 145c.

In the following description, when half the difference between the width w1 of the first metal layer 145a and the width w2 of the second metal layer 145b is referred to as the protrusion length d1 of a portion of the first metal layer 145a that protrudes past an end of the second metal layer 145b, the protrusion length d1 of the first metal layer 145a may be expressed by an equation d1=(w1−w2)/2. When half the difference between the width w2 of the second metal layer 145b and the width w3 of the third metal layer 145c is referred to as the protrusion length d2 of a portion of the third metal layer 145c that protrudes past the end of the second metal layer 145b, the protrusion length d2 of the third metal layer 145c may be expressed by an equation d2=(w3−w2)/2.

Depending on the degree to which the second metal layer 145b is etched, the protrusion length d1 of the first metal layer 145a and the protrusion length d2 of the third metal layer 145c may be different from the thickness h of the second metal layer 145b.

With reference to FIGS. 3 and 4, the wire 145′ may be made of the same material as the connection electrode 145 in the display area AA.

The wire 145′ may be made of the same layer as the connection electrode 145 in the display area AA.

The connection electrode 145 may have a thickness greater than that of the first and second gate electrodes 122 and 132 in the display area AA. Since the wire 145′ is made of the same material or the same layer as the connection electrode 145, which has a thickness greater than that of the first and second gate electrodes 122 and 132 in the display area AA, compared to a case where the wire 145′ is made of the same material or the same layer as the first and second gate electrodes 122 and 132, the wire 145′ has a greater thickness, which may increase the penetration path of moisture and oxygen.

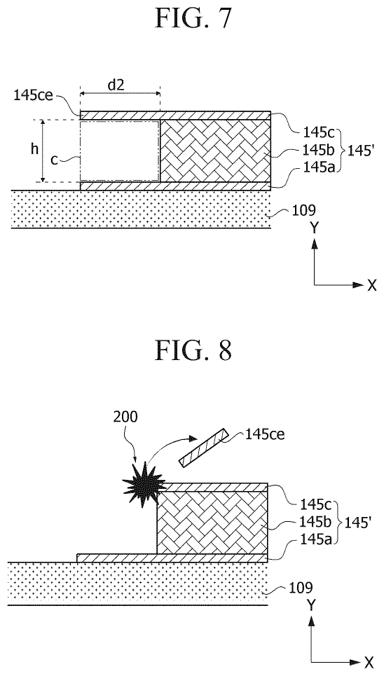

FIG. 7 is an enlarged cross-sectional view of a wire according to another embodiment of the present specification.

FIG. 8 is a view depicting an end portion being separated from the wire according to an embodiment of the present specification.

With reference to FIG. 7, when the protrusion length d1 of the first metal layer 145a and the protrusion length d2 of the third metal layer 145c are increased by etching the second metal layer 145b to increase the penetration path of moisture and oxygen, the empty space C under the third metal layer 145c becomes larger. In this case, the exposed end portion 145ce of the third metal layer may be not supported by the second metal layer 145b, and the exposed end portion 145ce of the third metal layer may be placed in a floating state.

With reference to FIG. 8, the exposed end portion 145ce of the third metal layer may be separated from the third metal layer 145c due to reasons such as a stacking process for forming the display panel of the display device 100, a collision with an equipment during a process, or gravity. That is, a defect may occur in which the exposed end portion 145ce of the third metal layer is separated from the wire 145′ (200).

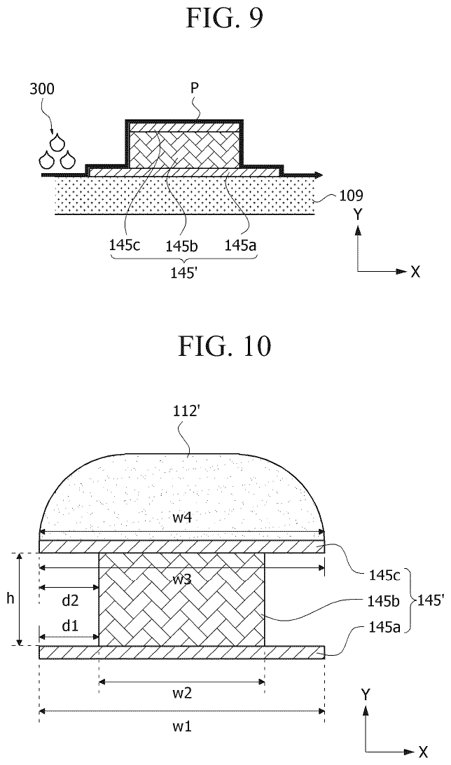

FIG. 9 is a view illustrating a penetration path of moisture and oxygen according to an embodiment of the present specification.

With reference to FIG. 9, as the exposed end portion 145ce of the third metal layer is separated (200), moisture and oxygen (300) may penetrate along the wire 145′.

As it is not possible to effectively block penetration of moisture and oxygen if the exposed end portion 145ce of the third metal layer is separated (200) due to a defect in the exposed end portion 145ce of the third metal layer, separation of the exposed end portion 145ce of the third metal layer (200) may result in a reliability defect of the display device 100 due to penetration of moisture and oxygen.

In other words, the penetration path P of moisture and oxygen may be lengthened by at least the protrusion length d2 of the exposed end portion 145ce of the third metal layer when the exposed end portion 145ce of the third metal layer of the wire 145′ is present in comparison to when the exposed end portion 145ce of the third metal layer of the wire 145′ is absent owing to its separation (200).

FIG. 10 is an enlarged cross-sectional view of the structure according to an embodiment of the present specification.

With reference to FIG. 10, a support layer 112′ may be formed on the wire 145′ to ensure the robustness of the exposed end portion 145ce of the third metal layer 145c. The support layer 112′ may be made of an organic material. The support layer 112 may include a lower surface that is directly on the third metal layer 145c, and an upper surface that is spaced apart from the lower surface and is not in contact with the third metal layer 145c. The upper surface of the support layer 112′ may be formed as a curved surface. A width of the lower surface of the support layer 112′ may be the same as the width w3 of the third metal layer 145c. The support layer 112′ may be made of the same material as the second protective layer 112 and may also be made of the same layer.

In the case that the support layer 112′ is formed on the wire 145′, although the exposed end portion 145ce of the third metal layer formed through etching of the second metal layer 145b becomes longer as shown in FIG. 7, when the support layer 112′ is present compared to when the support layer 112′ is absent, as the support layer 112′ supports the exposed end portion 145ce of the third metal layer, it is possible to prevent an event 200 in which the exposed end portion 145ce of the third metal layer from is separated.

Thereby, it is possible to minimize the possibility of a defect in the wire 145′. Furthermore, by forming the support layer 112′ on the wire 145′, the penetration path P of moisture and oxygen is lengthened by the protrusion length d2 of the third metal layer 145c corresponding to the exposed end portion 145ce thereof compared to when the support layer 112′ is not formed, so that it is possible to more stably prevent moisture and oxygen from penetrating into the display device 100.

When the support layer 112′ is formed on the wire 145′, the lower width w4 of the support layer 112′ may be equal to the width w3 of the third metal layer 145c.

The thickness of the third metal layer 145c in the Y direction may be less than the thickness of the first metal layer 145a in the Y direction and the thickness of the second metal layer 145b in the Y direction. During the process of forming the wire 145′, as the second metal layer 145b is etched, the exposed end portion 145ce of the third metal layer may be easily separated.

Hence, the protrusion length d1 of the first metal layer 145a may be formed to be the same as the protrusion length d2 of the third metal layer 145c or to be longer than the protrusion length d2 of the third metal layer 145c, so that it is possible to increase the length of the penetration path P of moisture and oxygen. For example, d1 may be greater than or equal to d2. With reference to FIG. 6A, the protrusion length d1 of a portion of the first metal layer 145a that protrudes past an end of the second metal layer 145b may be the same as the protrusion length d2 of a portion of the third metal layer 145c that protrudes past the end of the second metal layer 145b. With reference to FIG. 6B, the protrusion length d1 of a portion of the first metal layer 145a that protrudes past the end of the second metal layer 145b may be longer than the protrusion length d2 of a portion of the third metal layer 145c that protrudes past the end of the second metal layer 145b.

When the support layer 112′ is formed on the wire 145′, compared to when the support layer 112′ is absent as described above, the support layer 112′ supports the exposed end portion 145ce of the third metal layer, which may prevent the exposed end portion 145ce of the third metal layer from being separated.

Hence, since the protrusion length d1 of the first metal layer 145a may be formed to be shorter than the protrusion length d2 of the third metal layer 145c, the degree of freedom in designing the wire 145′ may be improved. For example, d1 may be less than d2. With reference to FIG. 6C, the protrusion length d1 of a portion of the first metal layer 145a that protrudes past the end of the second metal layer 145b may be shorter than the protrusion length d2 of a portion of the third metal layer 145c that protrudes past the end of the second metal layer 145b.

In addition, when the support layer 112′ is formed on the wire 145′, compared to when the support layer 112′ is absent as described above, since the support layer 112′ may support the exposed end portion 145ce of the third metal layer to thereby prevent the exposed end portion 145ce of the third metal layer from being separated, the protrusion length d1 of the first metal layer 145a and the protrusion length d2 of the third metal layer 145c may be formed to be greater than the thickness h of the second metal layer 145b in the Y direction. For example, a protrusion length d1 of a portion of the first metal layer 145a that protrudes past the end of the second metal layer 145b and a protrusion length d2 of a portion of the third metal layer 145c that protrudes past the end of the second metal layer 145b may be different from a thickness h of the second metal layer 145b. As shown in FIG. 7, the protrusion length d1 of the first metal layer 145a and the protrusion length d2 of the third metal layer 145c may be greater than the thickness h of the second metal layer 145b.

FIG. 11 is a cross-sectional view of the structure according to another embodiment of the present specification.

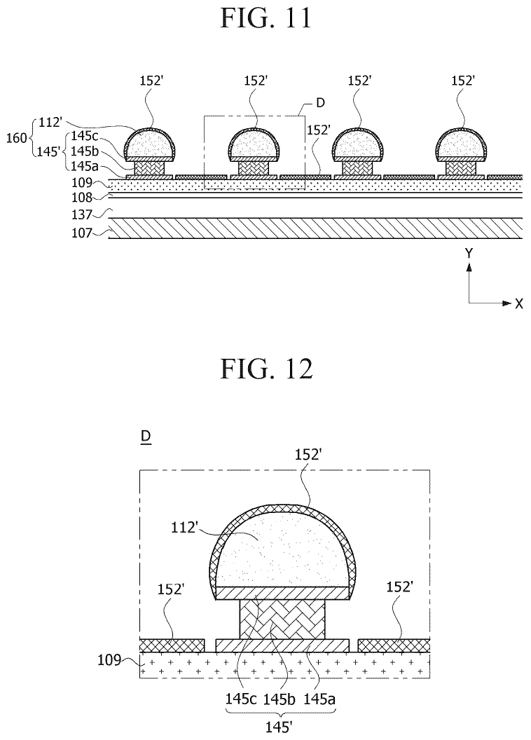

FIG. 12 is an enlarged view of region D in FIG. 11 according to another embodiment of the present specification.

With reference to FIGS. 11 and 12, it may be seen that it is possible to prevent moisture and oxygen from penetrating into the interior of the display device 100 along the organic material layer 152′ by disconnecting the organic material layer 152′ through the use of the structure 160. The emission layer 152 shown in FIG. 3 may be made of a material vulnerable to oxygen, moisture, and/or foreign substances, and penetration of oxygen, moisture, and/or foreign substances may affect the reliability of the display device 100 including the emission layer 152.

As shown in FIG. 4, the organic material layer 152′ may be disposed on the first protective layer 111 or the second protective layer 112. The organic material layer 152′ may be formed in the non-display area NA. For example, the organic material layer 152′ may be made of the same material as the emission layer 152 or may be made of the same layer as the emission layer 152.

The organic material layer 152′ may be formed through blanket deposition and may be formed in a structure being connected to the emission layer 152 in the display area AA, but embodiments of the present specification are not limited thereto.

If the organic material layer 152′ is not disconnected, as the organic material layer 152′ is connected to the emission layer 152, the connected structure of the emission layer 152 and the organic material layer 152′ may serve as a path through which oxygen and moisture may penetrate.

As a result, damage may occur to the emission layer 152 due to oxygen, moisture, and/or foreign substances coming from the outside through the organic material layer 152′ exposed during the process of forming the hole CH.

Accordingly, the display device according to an embodiment of the present specification is capable of blocking moisture, oxygen, and/or foreign substances that may move along the moisture penetration path by forming the structure 160 and the dam 190.

Additionally, the disconnection structure of the organic material layer 152′ may further block moisture, oxygen, and/or foreign substances that may move along the moisture penetration path.

With reference to FIG. 11, a wire 145′ may be formed in the non-display area NA. Since the wire 145′ has a specific thickness in the Y direction and the thickness of the organic material layer 152′ is relatively less than the specific thickness of the wire 145′, a first portion of the organic material layer 152′ on the support layer 112′ in the non-display area NA may be disconnected from a second portion of the organic material layer 152′ on the insulating layer in the non-display area NA at least through the wire 145′. The first portion of the organic material layer 152′ on the support layer 112′ may be disconnected from the second portion of the organic material layer 152′ on the insulating layer through a disconnection structure that includes the wire 145′ and the support layer 112′. Hence, the disconnection structure for the organic material layer 152′ may block penetration of moisture, oxygen, and/or foreign substances into the emission layer 152 of the display area AA. For example, the first portion of the organic material layer 152′ on the support layer 112′ may be spaced apart from the second portion of the organic material layer 152′ on the insulating layer by the wire 145′. So, the organic material layer 152′ may be linearly disconnected. Then, disconnection of the organic material layer 152′ may block penetration of moisture, oxygen, and/or foreign substances into the emission layer 152.

The first portion of the organic material layer 152′ on the support layer 112′ and the second portion of the organic material layer 152′ on the insulating layer may be made of the same material as the emission layer 152 of the display area AA. A thickness of the first portion of the organic material layer 152′ on the support layer 112′ may be less than a thickness of the support layer 112′. Also, the thickness of the first portion of the organic material layer 152′ on the support layer 112′ may be less than a thickness of the wire 145′. The first portion of the organic material layer 152′ on the support layer 112′ and the second portion of the organic material layer 152′ on the insulating layer may be formed on a same layer or made of the same material as the emission layer 152.

According to an embodiment of the present specification, the connection electrode 145 may be made of the same material as the wire 145′ and may be made of the same layer as the wire 145′.

For example, the connection electrode 145 may have a thickness greater than that of the first and second gate electrodes 122 and 132.

Hence, compared to a case where the wire 145′ is made of the same material as the first and second gate electrodes 122 and 132 or is made of the same layer as the first and second gate electrodes 122 and 132, since the wire 145′ is made of the same material as the connection electrode 145 or is made of the same layer as the first and second gate electrodes 122 and 132, the wire 145′ may have a greater thickness in the Y direction to thereby more effectively disconnect the organic material layer 152′.

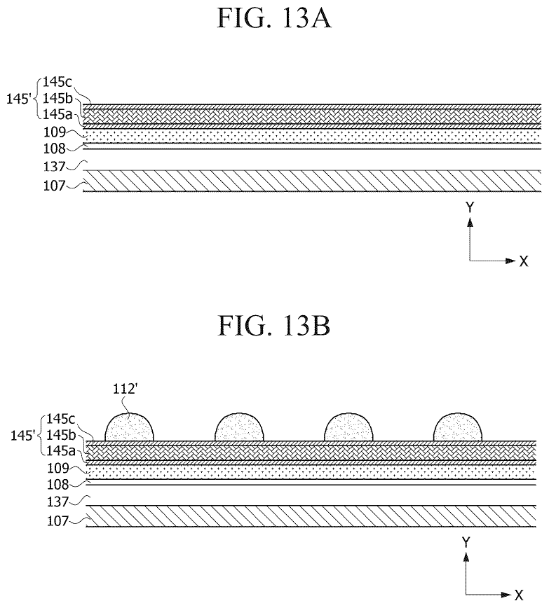

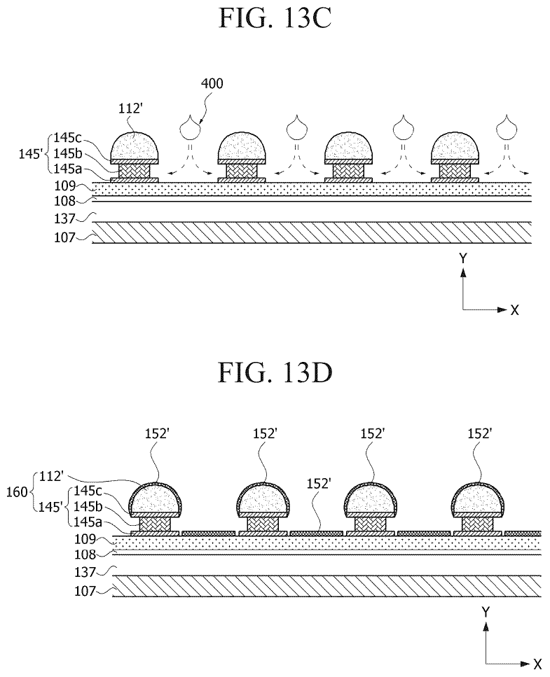

FIGS. 13A to 13D are views illustrating a method of manufacturing the display device according to an embodiment of the present specification.

With reference to FIG. 13A, a linear wire 145′ may be formed on the third buffer layer 107, the first upper interlayer insulating film 108, and the second upper interlayer insulating film 109. For example, the wire 145′ may be composed of a first metal layer 145a, a second metal layer 145b, and a third metal layer 145c, but embodiments of the present specification are not limited thereto.

The wire 145′ may be formed in and around a region corresponding to the hole CH in the non-display area NA. For example, the wire 145′ may be blanket-deposited in and around the region corresponding to the hole CH among the non-display area NA, but embodiments of the present specification are not limited thereto.

With reference to FIG. 13B, a support layer 112′ may be formed on the wire 145′. The support layer 112′ may be formed by use of a separate mask, but embodiments of the present specification are not limited thereto.

For example, the support layer 112′ may be made of an organic material. The organic material of the support layer 112′ may be different from an organic material of the organic material layer 152′. For example, the upper surface of the support layer 112′ may be a curved surface. Additionally, individual support layers 112′ may be formed to be spaced apart at regular intervals.

For example, since the upper surface of the support layer 112′ is formed as a curved surface, the length of the moisture penetration path in the support layer 112′ including a curved surface may be lengthened compared to when the support layer 112′ includes a flat surface. Hence, penetration of moisture and oxygen may be more effectively prevented by the support layer 112′ including a curved surface.

With reference to FIG. 13C, the wire 145′ may be formed by performing an etching process in the Y direction. An etching process may be performed on the formed wire 145′ in the X direction. Depending on the degree of reaction between the etchant 400 and the metal in the etching process, the rate at which the second metal layer 145b is etched in the X direction and the rate at which the first metal layer 145a and the third metal layer 145c are etched in the X direction may differ.

For example, the rate at which the second metal layer 145b is etched in the X direction may be greater than the rate at which the first metal layer 145a and the third metal layer 145c are etched. The distance between one support layer 112′ and its adjacent support layer 112′, which are spaced apart from each other, may be the interval between the support layer 112′ and its adjacent support layer 112′. The separation distance between one support layer 112′ and its adjacent support layer 112′ may be equal to the lower width w4 of the support layer 112′ shown in FIG. 10.

The protrusion length d1 of the first metal layer 145a and the protrusion length d2 of the third metal layer 145c may be determined depending on the degree of the etching process performed in the X direction. Even if the etching process proceeds, the support layer 112′ may remain on the wire 145′ and support the end portion 145ce of the third metal layer exposed by the etching process performed in the X direction so that it is not separated.

With reference to FIG. 13D, the organic material layer 152′ may be disconnected without being connected by the structure 160 including the wire 145′ and the support layer 112′.

The thickness of the organic material layer 152′ in the Y direction may be less than the thickness of the wire 145′ and the support layer 112′ in the Y direction, and the organic material layer 152′ may be disconnected due to the step of the structure 160.

Therefore, even if the hole CH is formed in the display panel and the end portion of the organic material layer 152′ is exposed, the organic material layer 152′ is disconnected by the structure 160 including the wire 145′ and the support layer 112′ and is not connected up to the emission layer 152 in the display area AA. Hence, the disconnection of the organic material layer 152′ may block penetration of moisture, oxygen, and/or foreign substances.

The display device according to one or more embodiments of the present specification may be described as follows.

A display device according to an embodiment of the present specification may include: a substrate including a display area, a non-display area, and a plurality of sub-pixels arranged in the display area, each of the plurality of sub-pixels including an emission layer in the display area; an insulating layer on the substrate; a plurality of wires spaced apart from each other on the insulating layer in the non-display area; and a support layer on each of the plurality of wires in the non-display area, wherein at least one of the plurality of wires includes a metallic material, and the support layer includes an organic material.

According to one or more embodiment of the present specification, the display device may further include an organic material layer on the support layer and the insulating layer in the non-display area, wherein a first portion of the organic material layer disposed on the support layer may be disconnected from a second portion of the organic material layer disposed on the insulating layer.

According to one or more embodiment of the present specification, the organic material layer on the support layer and the insulating layer may include a same material as the emission layer in the display area.

According to one or more embodiment of the present specification, the second portion of the organic material layer disposed on the insulating layer may be exposed through a hole in the non-display area.

A display device according to an embodiment of the present specification may include: a substrate including a display area, a non-display area, and a plurality of sub-pixels arranged in the display area, each of the plurality of sub-pixels including an emission layer in the display area; an insulating layer on the substrate; a wire on the insulating layer in the non-display area, the wire including a metal material; a support layer on the wire in the non-display area; and an organic material layer on the support layer and the insulating layer in the non-display area, wherein the wire and the support layer may have a specific thickness, a first portion of the organic material layer on the support layer is spaced apart by the specific thickness from a second portion of the organic material layer on the insulating layer, and the first portion of the organic material layer on the support layer and the second portion of the organic material layer on the insulating layer include a same material as the emission layer in the display area.

According to one or more embodiment of the present specification, the support layer may include an organic material that is different from an organic material of the organic material layer.

According to one or more embodiment of the present specification, the display device may further include: a second protective layer on the insulating layer and spaced apart from the second protective layer, the support layer including a same material as the second protective layer.

According to one or more embodiment of the present specification, the support layer may be on a same layer as the second protective layer.

According to one or more embodiment of the present specification, an upper surface of the support layer may include a curved surface.

According to one or more embodiment of the present specification, the wire may include: a first metal layer on the insulating layer; a second metal layer on the first metal layer; and a third metal layer on the second metal layer, the support layer on the third metal layer, wherein a material of the second metal layer may be different from at least one of a material of the first metal layer and a material of the third metal layer.

According to one or more embodiment of the present specification, the material of the first metal layer may be a same as the material of the third metal layer.

According to one or more embodiment of the present specification, the first metal layer and the third metal layer may include titanium and the second metal layer may include aluminum.

According to one or more embodiment of the present specification, a lower width of the support layer may be a same as a width of the third metal layer.

According to one or more embodiment of the present specification, a width of the first metal layer may be greater than a width of the second metal layer.

According to one or more embodiment of the present specification, a protrusion length of a portion of the first metal layer that protrudes past an end of the second metal layer may be a same as a protrusion length of a portion of the third metal layer that protrudes past the end of the second metal layer.

According to one or more embodiment of the present specification, a protrusion length of a portion of the first metal layer that protrudes past an end of the second metal layer may be shorter than a protrusion length of a portion of the third metal layer that protrudes past the end of the second metal layer.

According to one or more embodiment of the present specification, a protrusion length of a portion of the first metal layer that protrudes past an end of the second metal layer is longer than a protrusion length of a portion of the third metal layer that protrudes past the end of the second metal layer.

According to one or more embodiment of the present specification, a protrusion length of a portion of the first metal layer that protrudes past an end of the second metal layer and a protrusion length of a portion of the third metal layer that protrudes past the end of the second metal layer may be different from a thickness of the second metal layer.

According to one or more embodiment of the present specification, the protrusion length of the first metal layer and the protrusion length of the third metal layer may be greater than the thickness of the second metal layer.

According to one or more embodiment of the present specification, the display device may further include a gate electrode on the substrate in the display area, and a connection electrode on the gate electrode.

According to one or more embodiment of the present specification, the connection electrode is on a same layer as the wire and includes a same material as the wire.

According to one or more embodiment of the present specification, a thickness of the gate electrode may be less than a thickness of the wire.

According to one or more embodiment of the present specification, a thickness of the organic material layer may be less than the thickness of the wire.

A display device according to an embodiment of the present specification may include: a substrate including a display area, a non-display area, and a plurality of sub-pixels arranged in the display area, each of the plurality of sub-pixels including an emission layer in the display area; an insulating layer on the substrate; a wire on the insulating layer in the non-display area, the wire including a metallic material; a support layer on the wire without being on the insulating layer, the support layer including an organic material; a first organic material layer on the support layer in the non-display area; and a second organic material layer on the insulating layer in the non-display area, the second organic material layer disconnected from the first organic material layer at least through the wire.

According to one or more embodiment of the present specification, the second organic material layer may be disconnected from the first organic material layer through a disconnection structure comprising the wire and the support layer.

According to one or more embodiment of the present specification, the wire may include: a first metal layer on the insulating layer, the first metal layer having a first width; a second metal layer directly in contact with the first metal layer, the second metal layer having a second width that is less than the first width; and a third metal layer directly in contact with the second metal layer, the third metal layer having a third width that is greater than the second width.

According to one or more embodiment of the present specification, the first width may be a same as the third width.

According to one or more embodiment of the present specification, the support layer may include: a first surface that is directly on the third metal layer; and a second surface that is spaced apart from the first surface and has a curved surface, the second surface not in contact with the third metal layer, wherein a width of the first surface is a same as the third width.

According to one or more embodiment of the present specification, a thickness of the first organic material layer may be less than a thickness of the support layer, and the thickness of the first organic material layer may be less than a thickness of the wire.

According to one or more embodiment of the present specification, the display device may further include: a connection electrode that electrically connects the emission layer of a sub-pixel of the plurality of sub-pixels and a driving transistor, the connection electrode including a same material as the wire.

According to one or more embodiment of the present specification, the first organic material layer and the second organic material layer may be on a same layer or may include a same material as the emission layer.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

[Description of reference numerals]

| | |
|---|---|
| 100: Display device | AA: Display area |
| NA: Non-display area | SP: Sub-pixel |
| 101: Substrate | 120: First thin film transistor |
| 130: Second thin film transistor | 145: Connection electrode |
| 151: Anode electrode | 152: Emission layer |
| 153: Cathode electrode | 170: Encapsulation layer |
| 145′: Wiring | 152′: Organic material layer |
| 190: Dam | |

What is claimed is:

1. A display device comprising:
a substrate including a display area, a non-display area, and a plurality of sub-pixels arranged in the display area, each of the plurality of sub-pixels including an emission layer in the display area;
an insulating layer on the substrate;
a plurality of wires spaced apart from each other on the insulating layer in the non-display area; and
a support layer on each of the plurality of wires in the non-display area,
wherein at least one of the plurality of wires includes a metallic material, and the support layer includes an organic material.

2. The display device of claim 1, further comprising:
an organic material layer on the support layer and the insulating layer in the non-display area, wherein a first portion of the organic material layer disposed on the support layer is disconnected from a second portion of the organic material layer disposed on the insulating layer.

3. The display device of claim 2, wherein the organic material layer on the support layer and the insulating layer includes a same material as the emission layer in the display area.

4. The display device of claim 2, wherein the second portion of the organic material layer disposed on the insulating layer is exposed through a hole in the non-display area.

5. A display device comprising:
a substrate including a display area, a non-display area, and a plurality of sub-pixels arranged in the display area, each of the plurality of sub-pixels including an emission layer in the display area;
an insulating layer on the substrate;
a wire on the insulating layer in the non-display area, the wire including a metal material;
a support layer on the wire in the non-display area; and
an organic material layer on the support layer and the insulating layer in the non-display area,
wherein the wire and the support layer have a specific thickness,
wherein a first portion of the organic material layer on the support layer is spaced apart by the specific thickness from a second portion of the organic material layer on the insulating layer, and
wherein the first portion of the organic material layer on the support layer and the second portion of the organic material layer on the insulating layer include a same material as the emission layer in the display area.

6. The display device of claim 5, further comprising:
a second protective layer on the insulating layer and spaced apart from the second protective layer, the support layer including a same material as the second protective layer.

7. The display device of claim 5, wherein an upper surface of the support layer includes a curved surface.

8. The display device of claim 5, wherein the wire comprises:
a first metal layer on the insulating layer;
a second metal layer on the first metal layer; and
a third metal layer on the second metal layer, the support layer on the third metal layer,
wherein a material of the second metal layer is different from at least one of a material of the first metal layer and a material of the third metal layer.

9. The display device of claim 8, wherein the first metal layer and the third metal layer include titanium and the second metal layer includes aluminum.

10. The display device of claim 8, wherein a width of the first metal layer is greater than a width of the second metal layer.

11. The display device of claim 8, wherein a protrusion length of a portion of the first metal layer that protrudes past an end of the second metal layer is a same as a protrusion length of a portion of the third metal layer that protrudes past the end of the second metal layer.

12. The display device of claim 8, wherein a protrusion length of a portion of the first metal layer that protrudes past an end of the second metal layer is shorter than a protrusion length of a portion of the third metal layer that protrudes past the end of the second metal layer.

13. The display device of claim 8, wherein a protrusion length of a portion of the first metal layer that protrudes past an end of the second metal layer is longer than a protrusion length of a portion of the third metal layer that protrudes past the end of the second metal layer.

14. The display device of claim 8, wherein a protrusion length of a portion of the first metal layer that protrudes past an end of the second metal layer and a protrusion length of a portion of the third metal layer that protrudes past the end of the second metal layer is different from a thickness of the second metal layer.

15. The display device of claim 14, wherein the protrusion length of the first metal layer and the protrusion length of the third metal layer is greater than the thickness of the second metal layer.

16. The display device of claim 5, further comprising:
a gate electrode on the substrate in the display area; and
a connection electrode on the gate electrode.

17. The display device of claim 16, wherein the connection electrode is on a same layer as the wire and includes a same material as the wire.

18. The display device of claim 5, wherein a thickness of the organic material layer is less than a thickness of the wire.

19. A display device comprising:
a substrate including a display area, a non-display area, and a plurality of sub-pixels arranged in the display area, each of the plurality of sub-pixels including an emission layer in the display area;
an insulating layer on the substrate;
a wire on the insulating layer in the non-display area, the wire including a metallic material;
a support layer on the wire without being on the insulating layer, the support layer including an organic material;
a first organic material layer on the support layer in the non-display area; and
a second organic material layer on the insulating layer in the non-display area, the second organic material layer disconnected from the first organic material layer at least through the wire.

20. The display device of claim 19, wherein the second organic material layer is disconnected from the first organic material layer through a disconnection structure comprising the wire and the support layer.
